(19) United States
(12) Patent Application Publication
(10) Pub. No.: US 2025/0271527 A1
(43) Pub. Date: Aug. 28, 2025

(54) METHOD FOR AUTOMATICALLY DETERMINING A SET OF AT LEAST ONE OPTIMAL CHARACTERISTIC PARAMETER OF A MAGNETIC RESONANCE ACQUISITION SEQUENCE

(71) Applicants: UNIVERSITE DE BORDEAUX, BORDEAUX (FR); CENTRE HOSPITALIER UNIVERSITAIRE DE BORDEAUX, TALENCE cedex (FR); FONDATION BORDEAUX UNIVERSITÉ, BORDEAUX (FR); CENTRE HOSPITALIER UNIVERSITAIRE VAUDOIS, LAUSANNE (CH)

(72) Inventors: Aurélien MAILLOT, PARIS (FR); Aurélien BUSTIN, BORDEAUX (FR); Hubert COCHET, BORDEAUX (FR); Matthias STUBER, ROMANEL-SUR-LAUSANNE (CH)

(21) Appl. No.: 18/858,637

(22) PCT Filed: Apr. 20, 2023
(86) PCT No.: PCT/EP2023/060291

§ 371 Date: Oct. 21, 2024

(30) Foreign Application Priority Data
Apr. 22, 2022 (FR) FR2203766

(51) Int. Cl. G01R 33/56

(52) U.S. Cl. CPC G01R 33/5602; G01R 33/5607

(57) ABSTRACT

A method for determining an optimal characteristic set of at least one characteristic parameter of an image acquisition sequence of an area to be imaged by magnetic resonance configured to substantially cancel out medical signals from at least one predetermined tissue, the method including the selection, computer-implemented, of an optimal characteristic image having a greater number of pixels of intensity less than or equal to a given intensity threshold among a plurality of characteristic images of a characteristic area of the area to be imaged generated by respective acquisition sequences having distinct respective sets of at least one characteristic parameter, the optimal characteristic set being the characteristic set of the acquisition sequence by which the optimal characteristic image was generated.

### FIELD OF THE INVENTION

The invention relates to the field of magnetic resonance imaging (MRI), notably cardiac magnetic resonance imaging.

It relates to magnetic resonance imaging in which an acquisition sequence is configured to cancel out a signal of at least one predetermined tissue such as for example late gadolinium enhancement or LGE magnetic resonance imaging.

The reference technique for the assessment of regional scar formation and myocardial fibrosis is bright blood late gadolinium enhancement or BR-LGE imaging. In this type of imaging, the viable myocardial signal is canceled out using inversion-recovery pulses, which allows scars to be visualized with high contrast between healthy myocardial tissue and scars. However, for myocardial scars adjacent to the blood chambers of the heart (right and left ventricles), the high intensity of the signal from blood prevents clear visualization and accurate delimitation of scars, in particular subendocardial scars. In order to circumvent this problem, black blood LGE (BL-LGE) imaging techniques have been proposed. They make it possible to cancel out the signals from healthy myocardium and blood simultaneously, thus providing high contrast both between scars and between blood and between scars and healthy myocardium.

The cancelation of the blood signal, to obtain a “black blood” contrast, is obtained by applying, to an area to be imaged of a patient, a radio frequency (RF) inversion-recovery sequence comprising a 180° pulse followed by a T1-rho preparation module and a read module. The duration separating the 180° pulse and the read module is called the inversion time.

It is sought to acquire the signals to generate the image of the area to be imaged with an acquisition sequence such that the inversion time of the sequence is optimal so that at the moment of reading the longitudinal magnetizations, the longitudinal magnetizations of blood and healthy myocardium are canceled out, which makes it possible to obtain the MRI image exhibiting the best contrast between scars and adjacent blood and healthy myocardium. The choice of the inversion time is fundamental in so far as the contrast of the image has a direct impact on the visualization, detection and delimitation of scars and therefore on the diagnosis and prognosis of the patient.

However, this inversion time depends on the patient, the static magnetic field, as well as the duration separating the acquisition sequence and the injection of contrast product. It is therefore necessary to determine the optimal inversion time, for each patient, before acquiring medical images of the myocardium on which a specialist or a detection program is intended to detect or visualize and locate myocardial scars.

### PRIOR ART

Methods are known for automatically determining the optimal inversion time from MRI images acquired by means of inversion-recovery type acquisition sequences having respective distinct inversion times in BR-LGE MRI imaging, based on artificial intelligence techniques.

Notably, a method based on the analysis of the spatial and temporal characteristics of the different images by a neural network is known. A method based on a technique of segmentation by a convolutive neural network followed by analysis of pixel intensities in a region of interest obtained by the segmentation is also known.

However, the use of these methods in the clinic is not straightforward, as their installation on an MRI imaging device is complex (specific calculation libraries and software must be installed for these methods to work) and remains currently mainly used for research purposes at dedicated sites.

Patent U.S. Pat. No. 9,104,783B2 discloses a system for automatically determining imaging parameters for BL-LGE imaging based on a model linking the inversion time to the electrocardiogram (ECG). However, this method is completely dependent on ECG acquisition, the presence of blood flow, non-functional in the presence of blood stagnating on the walls, and restricted to 2D applications.

One aim of the invention is to limit at least one of the aforementioned drawbacks.

To this end, the invention relates to a method for determining an optimal characteristic set of at least one characteristic parameter of a medical signal acquisition sequence for the generation of a medical image of an area to be imaged by magnetic resonance, the acquisition sequence being configured to substantially cancel out medical signals from at least one predetermined tissue, the method comprising the selection, computer-implemented, of an optimal characteristic image having a greater number of pixels of intensity less than or equal to a given intensity threshold among a plurality of characteristic images of a characteristic area of the area to be imaged generated from signals acquired by respective acquisition sequences having distinct respective sets of at least one characteristic parameter, the optimal characteristic set being the characteristic set of the signal acquisition sequence by means of which the optimal characteristic image was generated.

In a particular embodiment, the medical signal acquisition sequence is a black blood late gadolinium enhancement acquisition sequence.

In a particular embodiment, the characteristic area only comprises parts of the myocardium and blood.

In a particular embodiment, the characteristic set is an inversion time.

In a particular embodiment, the method comprises determining the intensity threshold, this step comprising:
calculation of histograms of the characteristic images of the characteristic area,
determination of an intensity of the global maximum of the histograms.

In a particular embodiment, the method comprises the selection of characteristic images of the characteristic area among images of the area to be imaged.

In a particular embodiment, the method comprises the following sequence of steps:
acquisition of signals by means of the respective acquisition sequences,
generation of characteristic images from the signals.

Advantageously, the sequence of steps and the selection of the optimal characteristic image are repeated with inversion times different from those of the acquisition sequences when the optimal inversion time is a maximum or minimum inversion time of the acquisition sequences.

The invention also relates to a method for generating a medical image of the area to be imaged comprising the determination of the optimal set of at least one characteristic parameter by the method according to the invention. This method further comprises the acquisition of medical signals by the medical acquisition sequence having the optimal characteristic set and the generation of the medical image from the medical signals.

The invention relates to a processing system comprising a processor configured to implement the steps of the method according to the invention.

The invention also relates to a computer program product comprising instructions which, when the program is executed by a computer, lead the latter to implement the steps of the method according to the invention.

The invention further relates to a computer-readable recording medium comprising instructions which, when executed by a computer, lead the latter to implement the method according to the invention.

Furthermore, the invention relates to a magnetic resonance imaging system comprising a magnetic resonance system comprising a static magnetic field generator, a gradient generator, a radio frequency device and a processing and control system configured to implement the calculation steps of the method according to the invention and to control the magnetic resonance system such that the imaging system implements the method according to the invention.

### Advantages

The method according to the invention makes it possible to determine the inversion time in a reliable, robust, inexpensive in terms of calculations, reproducible and simple manner.

It is easily integrated into an existing MRI device without significant modification of existing acquisition sequences.

Moreover, this method does not give any additional workload to the handler.

Further, the method is fast (of the order of several tens of ms), which is advantageous in so far as the optimal inversion time is likely to evolve during the examination given the kinetics of gadolinium elimination.

The method according to the invention makes it possible to choose the pitch between the inversion times or, more generally, between the values of the parameters of the different characteristic sets of the different acquisition sequences, which makes it possible to obtain the optimal inversion time or the optimal set with good precision, which is ultimately favorable for the correct detection and precise location of the characteristics.

### BRIEF DESCRIPTION OF THE FIGURES

Other features and advantages of the invention will become clearer upon reading the following detailed description, in reference to the appended figures, that illustrate:

FIG. 1: a schematic representation of the MRI imaging system according to the invention,

FIG. 2: a schematic representation of a BL-LGE MRI acquisition sequence,

FIG. 3: a schematic representation of the steps of the method according to a first embodiment,

FIG. 4: a flowchart of the steps of an MRI image acquisition method according to the invention,

FIG. 5: a flowchart of the steps of an exemplary embodiment of a global method according to the invention.

### DESCRIPTION OF THE INVENTION

The invention relates to the field of magnetic resonance imaging or MRI.

It relates more particularly to MRI imaging wherein one wishes to configure a medical signal acquisition sequence to obtain a substantially null signal for one or more predetermined tissues. In other words, it is desired to configure the medical signal acquisition sequence to generate a substantially black image of a predetermined tissue.

It relates, for example, to black blood MRI imaging.

The invention notably relates to magnetic resonance imaging requiring the injection of a contrast product, for example gadolinium.

It relates, for example, to black blood late gadolinium enhancement (BL-LGE) imaging.

The invention applies to cardiac imaging, but also to angiography.

### MRI System

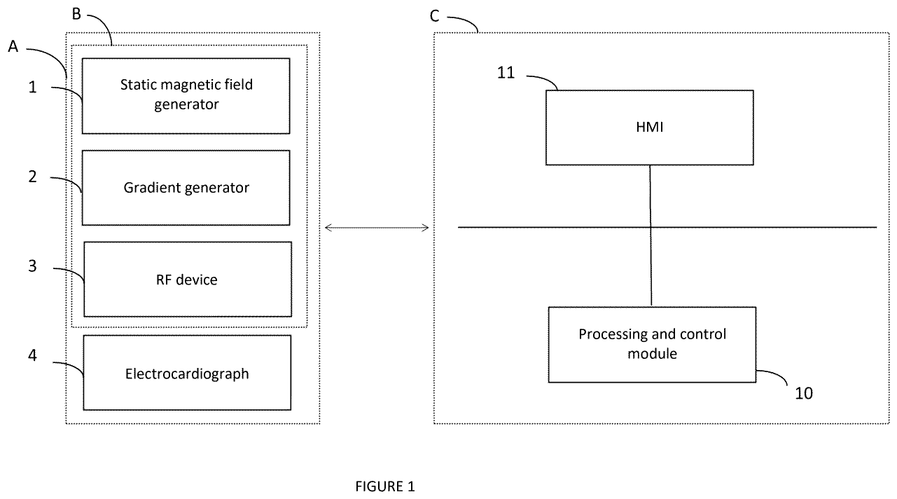

FIG. 1 schematically shows a magnetic resonance imaging system according to the invention comprising a set A of excitation and measurement equipment and a processing and control system C.

In a manner known per se, the set A of excitation and measurement equipment comprises an MRI imaging device B comprising a static magnetic field generator 1 comprising a main polarization magnet, a gradient generator 2 and a radio frequency device 3.

The static magnetic field generator 1 comprises a main polarization magnet intended to generate a substantially uniform polarization static magnetic field in a polarization area (usually a tunnel) intended to comprise the area to be imaged of the patient, for example the heart.

The gradient generator 2 comprises three gradient coils or solenoids disposed and configured to vary the intensity of the magnetic field in the polarization area along respective orthogonal axes conventionally noted x, y, and z fixed with respect to the polarization area. The choice of the intensities circulating in these coils makes it possible to select, from several possible, a thickness and a section plane in which the magnetization of the area to be imaged of the patient received in the polarization area will be measured.

The radiofrequency device 3 comprises coils or solenoids and is capable of generating MRI acquisition sequences comprising 180° inversion pulses, magnetization preparation modules of the area to be imaged and modules for reading signals from the area to be imaged.

Generally, the acquisition sequence is composed of sub-sequences called modules each comprising at least one radio frequency pulse of predetermined and adjustable frequency, shape, duration, phase, amplitude.

The preparation module is configured to excite, i.e. change the direction of magnetization of the tissues of the area to be imaged.

The read module is configured to measure the magnetization of the area to be imaged resulting from the preparation module.

The set A advantageously comprises an electrocardiograph 4 intended to acquire an electrocardiogram of the patient.

The processing and control system C comprises a processing and control module 10 configured to generate controls intended for the MRI device B, notably intended for the RF device 3, to generate the acquisition sequences and to generate two-dimensional grayscale images of the area to be imaged from the signals measured by the RF magnetic field generator by reconstruction techniques known to those skilled in the art.

The generated image is a grayscale matrix image. It comprises a set of pixels each characterized by an intensity I capable of taking a set of N values (N being a whole finite greater than 1) corresponding to N gray levels ranging from 0 and N−1. For example, this value may take 256 values between 0 and 255 but N is not limited to 256.

Representations of the images generated by the processing and control module 10 are intended to be displayed on a screen of the human-machine interface 11 of the processing and control system C.

### Acquisition Sequence

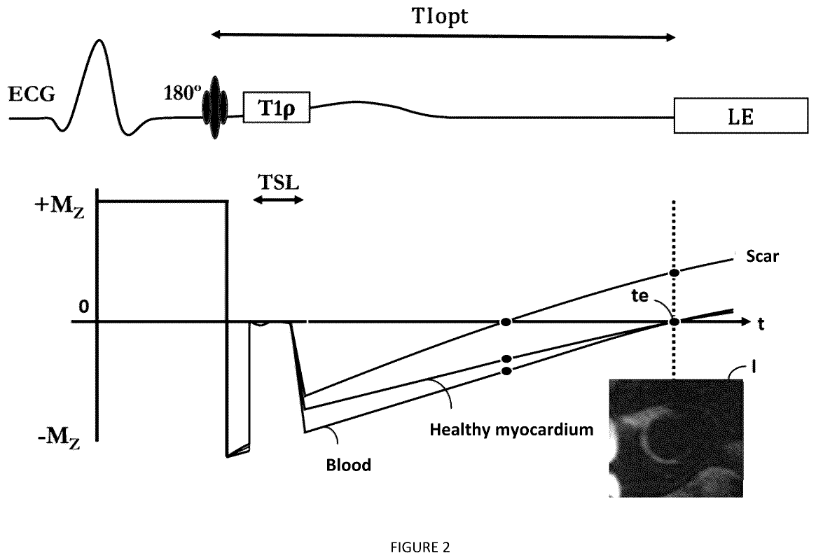

FIG. 2 shows an example of a black blood MRI acquisition sequence of an image of the myocardium. A schematic representation of an electrocardiogram (ECG) able to be acquired by the electrocardiograph 4 during a heartbeat as well as the acquisition sequence applied to the area to be imaged are shown in the upper part of FIG. 2. The lower part of FIG. 2 represents the variation of the longitudinal magnetization of the tissues of the area to be imaged as a function of time t as well as an image I reconstructed from signals acquired during a read module beginning at an instant t=te corresponding to the cancelation of the longitudinal magnetizations of blood and healthy myocardium.

For the BL-LGE MRI acquisition, a gadolinium-based contrast product is advantageously injected intravenously into the patient, 10 to 15 minutes before the application of the acquisition sequences so as to obtain images exhibiting maximum contrast between scars and healthy tissues and blood. At the heart, the contrast is rapidly eliminated from healthy myocardium, but accumulates prolongedly in myocardial scars. The effect of gadolinium is to shorten the relaxation time T1 of the tissues where it accumulates. The relaxation of the magnetization of scars following a pulse is thus faster than that of blood and healthy myocardium.

The aim is to generate images having black blood contrast. In an image of this type, the intensity of the pixels corresponding to blood is null (black pixels) or substantially null because it is acquired when the longitudinal magnetization of the blood is null.

In order to generate such an image, the RF device 3 generates an inversion-recovery acquisition sequence.

This acquisition sequence comprises a preparation module comprising an inversion pulse noted 180° in FIG. 2, which flips the longitudinal magnetization of the tissues of the imaging area in the opposite direction, i.e. which inverses the longitudinal magnetization. FIG. 2 shows that the magnetization of the area to be imaged changes from Mz to −Mz under the effect of the inversion pulse. Due to the longitudinal relaxation, the longitudinal magnetization of the different tissues present in the area to be imaged increases to return to its initial value, passing through the null value. Naturally, the relaxation kinetics of different tissues are different.

In a manner known per se, the preparation module comprises, for example, a T1-rho adiabatic module (T1p) of duration noted TSL (acronym for “Time of Spin Lock”) or a T2-weighted module, or of the MTC type (acronym for “Magnetization Transfer Contrast”).

The preparation module (180°, T1p) is configured so that the longitudinal magnetization of blood and that of healthy myocardium are canceled out at the same instant te.

At this same instant te, the longitudinal magnetization of the scars is significantly greater than zero. By acquiring signals from the area to be imaged at this instant te, an image is obtained with a very high contrast between the pixels corresponding to blood and healthy myocardium, which are black, and the pixels corresponding to scars, which are generally white.

The inversion-recovery sequence next comprises a read module LE comprising a 90° pulse applied at the instant te and a read gradient to read the transverse magnetization of the area to be imaged.

The inversion time TI is the time separating the 180° pulse and the read module, i.e. the first instant of acquisition of the image in the Fourier domain. In order to obtain the best contrast between myocardial scars and blood and healthy myocardium, it is sought to start the read sequence at the instant te when the longitudinal magnetizations of blood and myocardium cancel out in order to generate the image exhibiting the best contrast. The inversion time is then optimal, it is noted TIₒₚₜ in FIG. 2.

### Determining the Optimal Inversion Time TI_{Opt}

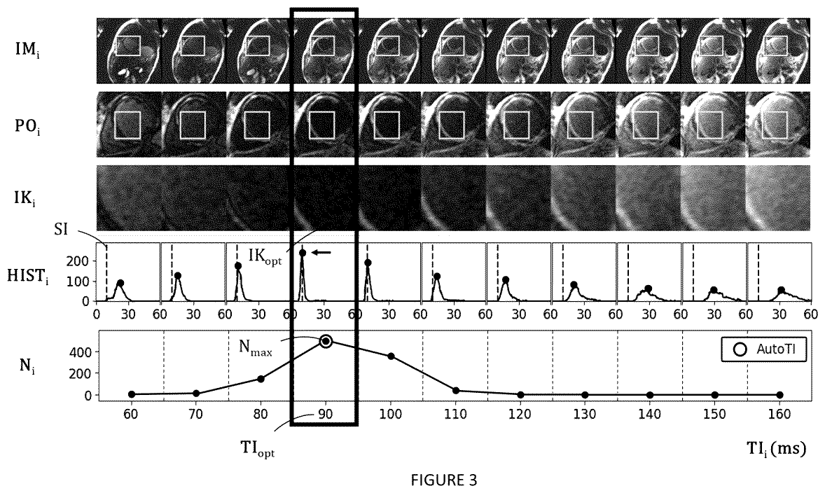

FIG. 3 shows the steps of the method according to the invention.

The method according to the invention is a computer implemented method for determining the optimal inversion time TIₒₚₜ from a plurality of characteristic images IKᵢ of a characteristic area of the area to be imaged generated by applying acquisition sequences differing from each other only by their respective inversion times TIᵢ.

As can be seen in FIG. 3, the characteristic images IKᵢ have different contrasts (with i=1 to K, K being at least equal to 2 and equal to 11 in the non-limiting example of FIG. 3).

This optimal inversion time TIₒₚₜ is advantageously stored in a memory of the system C and used, by the processing and control module 10, to generate a control intended for the system A, in particular the RF device 3 in order that it acquires so-called medical signals, by a so-called medical acquisition sequence, wherein the inversion time TI is the optimal inversion time TIₒₚₜ so that the processing and control device generates an image from these signals.

According to the invention, the method for automatically determining the optimal inversion time TIₒₚₜ comprises, as can be seen in FIG. 3, the selection, implemented by computer, of an optimal characteristic image IKopt, which has a greater number of pixels of intensity less than or equal to a given intensity threshold SI, from the plurality of characteristic images IKᵢ with i=1 to K. The intensity threshold SI used is the same for all the images IKᵢ with i=1 to K.

The optimal inversion time TIₒₚₜ is the inversion time TIᵢ of the acquisition sequence by means of which the optimal elementary image IKₒₚₜ was generated.

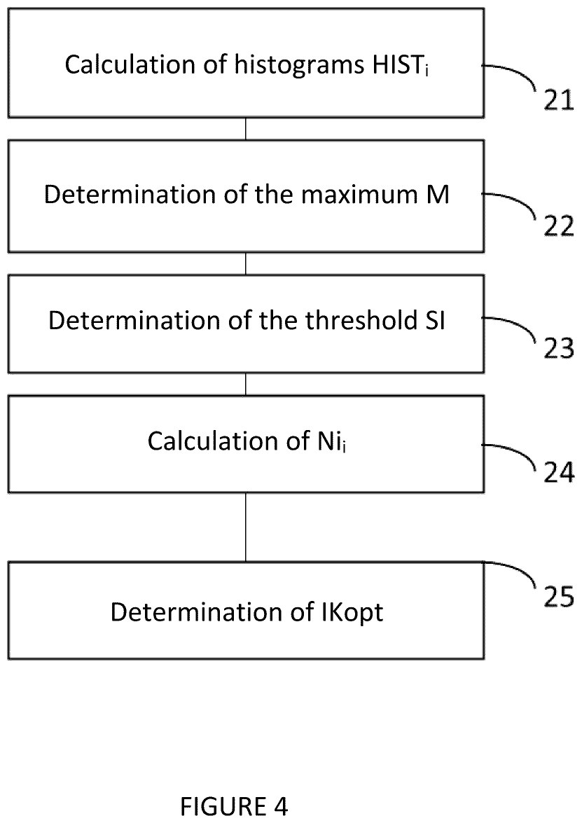

We will now describe in more detail a preferred embodiment of the step of selection, shown in FIG. 4, of the optimal elementary image IKₒₚₜ which is the elementary image IKᵢ which has a greater number of pixels of intensity less than or equal to an intensity threshold SI, among the elementary images IKᵢ.

This step advantageously comprises the following steps, each of which is implemented by computer, by the processing and control module 10:
calculation 21 of histograms HISTᵢ of characteristic images IKᵢ for i=1 to K,
determination 22 of the global maximum M of the histograms HISTᵢ by a conventional method for detecting a global maximum,
determination 23 of an intensity SI of the global maximum M

The intensity threshold SI is the intensity of the global maximum M of the histograms HISTᵢ.

Each histogram HISTᵢ contains, for each of the N possible values of intensity I, the number of pixels of the image having this intensity I.

For reasons of clarity, the histograms in FIG. 3 are partial. Only the portions of these histograms concerning the intensity values (grayscale) comprised between 0 and 60 are represented in FIG. 3.

The method next comprises the following steps:
calculation 24, for each characteristic image IKᵢ of the number NIᵢ of pixels of the image IKᵢ having an intensity less than or equal to the intensity threshold SI,
determination 25 of the optimal characteristic image IKₒₚₜ having, among the images IKᵢ with i=1 to K, the largest number NIᵢ of pixels of intensity less than or equal to SI.

The optimal inversion time TIₒₚₜ is the inversion time of the acquisition sequence by means of which the signals used to generate the optimal characteristic image IKₒₚₜ having the largest number of pixels of intensity less than or equal to the intensity threshold SI.

Put another way, the proposed method makes it possible to select the image that has the most pixels of low intensity.

The fact of calculating the intensity threshold SI from the characteristic images IKᵢ makes it possible to adapt the threshold as a function of the patient and to select a reliable optimal inversion time.

Furthermore, it should be noted that in images comprising only myocardium and blood, only scars normally exhibit a high intensity on the image obtained from an acquisition sequence having the TIₒₚₜ. It may happen that the image exhibits high intensity artifacts. The intensity threshold SI used in the method according to the invention is not affected by the value of these pixels which would have been different with a threshold equal to the mean value of the maximums of the histograms.

In an alternative, the intensity threshold SI constitutes data used by the method according to the invention. This intensity threshold SI is, for example, previously stored in a memory of the system C. The method is then devoid of steps 22 and 23.

### Characteristic Images

Advantageously, it is desirable to configure the acquisition sequence to simultaneously acquire substantially null signals of at least one tissue of the characteristic area. Put another way, the tissue(s) concerned simultaneously exhibit substantially null longitudinal magnetization at the moment of the read sequence, i.e. the image of this/these tissue(s) reconstructed from the signals from this/these tissue(s) measured during the acquisition sequence is black or substantially black.

Advantageously, the characteristic area comprises this/these tissue(s).

When applied to BL-LGE cardiac imaging, the method according to the invention advantageously uses characteristic images IKᵢ of a characteristic area comprising only a part of the myocardium and blood.

The method according to the invention is then very reliable. Indeed, in this case, the acquisition sequence is configured to substantially cancel out the longitudinal magnetizations of healthy myocardium and blood simultaneously. The area of interest is the part of the myocardium affected by scars. This area is minority, the image will be mostly substantially black.

In angiography, we want to visualize the vessels and therefore the blood. The acquisition sequence is configured to substantially cancel out the signal from the myocardium and other tissues such as the back and chest muscles, as opposed to that of blood. Advantageously, a contrast product, for example gadolinium, is injected intravenously and the acquisition sequence is implemented in a non-late manner so that the blood appears white (bright) on the images.

Advantageously, the characteristic area only comprises tissues of which it is desired to obtain substantially null signals by means of the acquisition sequence.

Advantageously, the characteristic area only comprises tissues of which it is desired to acquire substantially null signals by means of the acquisition sequence and blood and mostly tissues for which it is desired to acquire signals substantially.

### Determination of a Characteristic Set

The invention relates more generally to a method for automatically determining an optimal characteristic set. The characteristic set consists of one or more parameters characteristic of an MRI acquisition sequence. The aim of the invention is to determine the optimal characteristic set comprising respective values of characteristic parameters such that the contrast of the image acquired by means of an acquisition sequence characterized by this characteristic set is maximum.

The steps of the method implemented are the same as the steps described with reference to FIG. 4.

The method then uses characteristic images of the characteristic area acquired by respective acquisition sequences differing only by their characteristic sets, i.e. by values of the parameters characteristic of the set.

The characteristic set may notably comprise at least one parameter taken from: the inversion time TI, the preparation module, a parameter of the preparation module, for example the TSL duration of the module in T1ρ, the number of pulses of the preparation module, the time spacing between two consecutive pulses of the preparation module, the intensity, the phase shift, the frequency, the amplitude of each pulse, the shape, the duration, the phase, of at least one or each of the pulses of the preparation module.

Each characteristic parameter may take different values. Put another way, each characteristic parameter is adjustable by the MRI system A, C.

The choice of the value of each of the characteristic parameters has an influence on the evolution of the value of the longitudinal magnetization of each tissue present in the image as a function of time and therefore contrast of the image.

These parameters may be independent of each other or not.

The optimal characteristic set is the inversion time of the signal acquisition sequence by means of which the image IKₒₚₜ having the largest number of pixels of intensity less than or equal to the intensity threshold SI was generated.

### Global Method

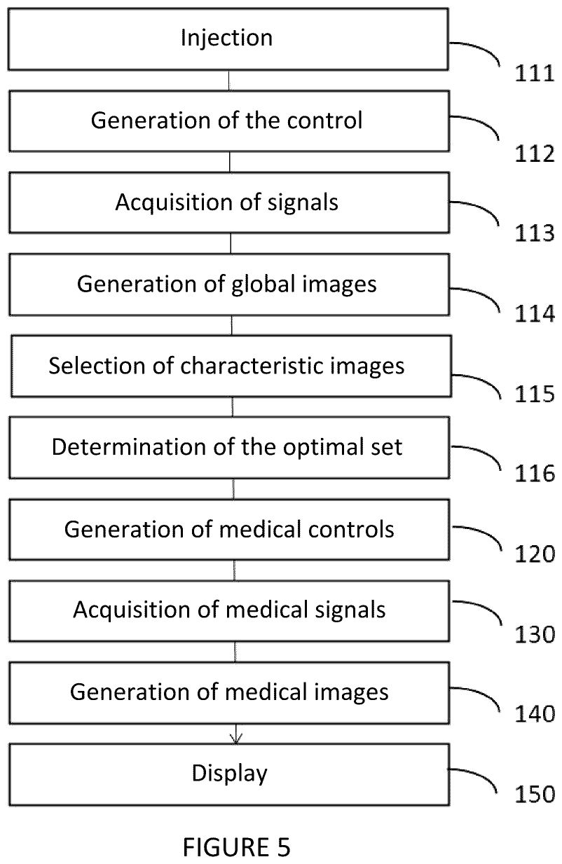

The invention also relates to a global method for generating medical images of an area to be imaged, the steps of which are represented in FIG. 5.

This global method comprises a method for determining an optimal characteristic set comprising, for example:
possible injection 111 of a contrast product, for example gadolinium, intravenously into the patient,
generation 112 of a control to acquire signals of the area to be imaged by means of K respective acquisition sequences differing only by their characteristic set of at least one characteristic parameter, by the processing and control module 10,
acquisition 113 of the signals of the area to be imaged using Ks acquisition sequences by the RF device 3,
generation 114 of K two-dimensional global images IMᵢ (i=1 to K) of the area to be imaged by means of signals acquired during step 112, by the processing and control module 10,
selection 115 of the K characteristic images IKᵢ (i=1 to K) being portions of the respective global images IMᵢ, by the processing and control module 10,
determination 116 of the optimal set, for example the optimal inversion time TIₒₚₜ by means of the method for determining the optimal set previously described from the characteristic images IKᵢ, by the processing and control module 10.

The global method next comprises the following steps:
generation 120, by the processing and control module 10 of an acquisition control for acquiring the so-called medical signals for generating a set of at least one medical image of the area to be imaged from at least one acquisition sequence characterized by the optimal characteristic set,
acquisition 130, by the RF device, 3, of medical signals of the area to be imaged by means of the acquisition sequence(s) characterized by the optimal characteristic set,
generation 140, by the processing and control module 10, of the set of at least one medical image of the area to be imaged from the medical signals of the area to be imaged acquired in step 130,
display 150 of representations of medical images, by the human-machine interface 11.

Advantageously, during step 130, signals are acquired which make it possible to generate, during step 140, several medical images according to different section planes. To this end, the gradient generator generates different gradients during the acquisition sequences.

The invention also relates to the system A, C configured to implement the method according to the invention.

Advantageously, step 113 of acquisition is implemented between 10 and 15 minutes after the injection of gadolinium in the non-limiting case of BL-LGE imaging. It is triggered and controlled by the controls generated during step 112.

The signals of the area to be imaged are acquired, in step 113, by means of respective acquisition sequences differing from each other only by their respective characteristic sets. Furthermore, the other acquisition conditions, namely the magnetic field generated by the static magnetic field generator 1 and the gradient generated by the gradient generator are the same during these sequences.

The acquisition sequences are advantageously synchronized, by the processing and control module 10, with the heart rhythm, using the signals measured by the electrocardiograph 4 implemented during respective consecutive heart beats. An acquisition sequence is implemented at each heartbeat.

Thus, the global images IMᵢ are images of the heart produced according to the same section plane of the area to be imaged.

In cardiac imaging, the section plane is, for example, a small axis section plane. This section plane has the advantage of allowing the visualization of the entire myocardium in section and thus favors the detection and visualization of myocardial scars.

Other section planes may be advantageous for other types of detection, for example for functional imaging.

Advantageously, in the case of BL-LGE cardiac imaging, the acquisition sequences comprise respective inversion times ranging from 60 ms to 160 ms when the static magnetic field is 1.5 Tesla. Indeed, the applicant has found, by means of tests carried out on different patients, that the inversion times are conventionally between 60 ms and 160 ms for this type of imaging.

In general, the respective inversion times may be comprised between 0 sec and 300 ms.

For example, the acquisition sequences comprise different inversion times ranging from 60 ms and 160 ms and separated two to two by a pitch.

The pitch for example equals 10 ms.

In an alternative, the pitch is less than or greater than 10 ms. The choice of pitch depends on the compromise chosen between the acquisition time (the smaller the pitch, the greater the number of images) and the precision with which it is wished to define the optimal inversion time, knowing that below a certain pitch, the gain in precision on the optimal TI and therefore in contrast on the medical image is not perceptible to the naked eye on medical images for diagnosis.

The pitch may be fixed or variable over the interval.

Step 114 of generating two-dimensional global images is performed by means of MRI image reconstruction techniques known to those skilled in the art. Notably, parallel reconstruction algorithms such as the GRAPPA or SENSE algorithm (acronym of “SENSitivity Encoding”) are known.

Step 115 of selecting the characteristic images IKᵢ, i.e. portions of the images IMᵢ, may be performed in different ways.

In a particular embodiment, the selection step 114, implemented by computer, for example by the system C, comprises two steps:
selection, on each image IMi of an image portion POᵢ of the image IMᵢ, this image portion POᵢ is represented in the second line of FIG. 3 and corresponds to the portion POᵢ of the image IMᵢ delimited by the white frame represented on the image IMᵢ,
selection, for each image portion of image POᵢ, of the characteristic image IKᵢ being a portion of the image portion POᵢ this characteristic image IKᵢ is represented in the third line of FIG. 3 and corresponds to the portion of the image POᵢ delimited by the white frame represented on the image portion POᵢ.

The selection of the image portion POᵢ comprises, for example, the acquisition, by the processing and control module 10, of the coordinates, dimensions and orientation of a first frame completely surrounding and delimiting the image portion POᵢ. This frame is the white frame shown on the images IMᵢ in FIG. 3.

In cardiac imaging, this frame is advantageously centered on the heart, delimits the heart section in the section plane and contains the entire heart section located in the section plane. Advantageously, the frame is a polygon, for example a rectangle, each side of which delimits the section of the heart in the section plane.

This frame is, for example, drawn by an operator on a representation of one of the images IMᵢ displayed on a screen of the HMI 11 by means of an element of the HMI, for example a mouse of the HMI, the movement of which causes the movement of a cursor on the HMI screen.

This frame is, for example, a Shim box, usually drawn by the user on one of the images to select the portion POᵢ within which the magnetic field must be homogenized.

The dimensions and orientation coordinates of this frame in the image marker are calculated by the processing and control module 10 from the positions, orientation and dimension of the frame on the screen and stored in a memory of the system C. The processing module 10 selects the portions POᵢ of the images IMᵢ from the coordinates, dimensions and orientation of the frame. The portions POᵢ are stored in the memory of the system C.

Advantageously, the selection of the characteristic image IKᵢ is the selection of a central portion of the image portion POᵢ being equal to the size of the portion of the image POᵢ divided by a predetermined factor.

In cardiac imaging, the factor is advantageously defined such that the characteristic image IKᵢ only comprises blood and a part of the myocardium.

The factor is, for example, comprised between 2 and 3. For example, it is equal to 2.5. The applicant tested different factor values on different patients in order to obtain this factor.

In an alternative, the selection 115 of the K characteristic images IKᵢ (i=1 to K) comprises a segmentation step known to those skilled in the art implemented by the processing and control module 10 so as to select the portion POᵢ of the image that completely surrounds and delimits the section of the heart in the section plane. Such a segmentation step is, for example, described in the following document: “Automated Deep-Learning-based Inversion Time Selection for Cardiac Late Gadolinium Enhancement Imaging, ISMRM 2020, Seung Su Yoon, Michaela Schmidt, Bernd J Wintersperger, Teodora Chitiboi, Puneet Sharma, Christoph Tillmanns, Andreas Maier, and Jens Wetzl”, the algorithm having to be trained by images acquired by a BL-LGE acquisition sequence in the case of BL-LGE imaging and in the following document “Dark blood ischemic LGE segmentation using a deep learning approach” C. Torlasco et al, European Heart Journal—Cardiovascular Imaging, Volume 22, Issue Supplement_2, June 2021).

In an alternative, the selection 115 comprises the acquisition of a position of the center of the heart section in the section plane of the images on one of the images IMᵢ and the determination, by the processing and control module 10, of a portion of the image IMᵢ centered on the image and of a predefined size stored in a memory of the system C.

The selection step 115 makes it possible, in cardiac imaging, to select a part of the image IMᵢ comprising only blood and myocardium. It does not require the implementation of precise heart segmentation algorithms.

In an alternative, the characteristic images IKᵢ are the global images IMᵢ or the portions of images POᵢ.

The step 116 of determination of the optimal set or more specifically the optimal inversion time TIₒₚₜ is implemented as described previously, by the processing and control module 10.

Advantageously, when the optimal inversion time TIₒₚₜ is the maximum inversion time, or respectively the minimum inversion time, of the acquisition sequences of the signals used to generate the characteristic images IKᵢ, then the sequence of steps 112 to 116 of the method is repeated with inversion sequences having respective acquisition times whose minimum inversion time is the maximum inversion time of the acquisition sequences used to generate the images IKᵢ, or respectively the maximum inversion time is the minimum inversion time of the acquisition sequences used to generate the images IKᵢ. This makes it possible to find the really optimal inversion time.

### Hardware Part

From a hardware point of view, the processing and control system C, shown in FIG. 1, may be seen as a calculator interacting with a computer program product.

The system C is a computer, for example, a microcomputer, a network of computers, an electronic component, a tablet, a smartphone, or a personal digital assistant (PDA).

The system C comprises the processing and control module 10. This processing and control module comprises, for example, one or more processors capable of interpreting instructions in the form of a computer program, a programmable logic circuit, such as an application-specific integrated circuit (ASIC), a field-programmable gate array (FPGA), a programmable logic device (PLD) and programmable logic arrays (PLA), a system on chip (SOC), an electronic board in which the steps of the method according to the invention are implemented in hardware elements. Steps of the method according to the invention may be executed by a processor, in a simultaneous or sequential manner and/or by one or more processors.

The processing and control module 10 comprises a data processing circuit for performing calculations, a memory operationally coupled to the data processing circuit, a computer readable medium and optionally a reader adapted to read the computer readable medium.

The system C also comprises the IMH 11 comprising an input device, an output device, and a communication device.

Each function of the system C is executed by causing the data processing circuit to read a predetermined program on hardware such as the memory of the processing and control module 10 such that the data processing circuit performs calculations, controls communications made by the communication device and reads and/or writes data to the memory of the computing module and the computer-readable medium.

The method is executed on a single computer or on a system distributed between several computers (notably via the use of cloud computing).

The memory is a computer readable recording medium, and may be configured with, for example, at least one of the following elements: a ROM (Read-Only Memory), an EPROM (Erasable Programmable Read-Only Memory), an EEPROM (Electrically Erasable Programmable Read-Only Memory), a RAM (Random Access Memory) and other suitable storage media. The memory may include an operating system and load the programs according to the invention. It includes registers adapted to record parameter variables created and modified during the execution of the aforementioned programs.

The program product may comprise the computer-readable recording medium which is a tangible device, not being a transient signal in itself, may be configured with, for example, at least one of the following elements: a removable medium, for example, but not limited to, a magneto-optical disk (for example, a Compact Disk Read-Only Memory (CD-ROM), a Digital Versatile Disk (DVD), a removable disk, a hard disk drive, a smart card, a flash memory device (for example, a card, a key), a magnetic strip, a database, a server, and another suitable storage medium.

In an alternative, the program instructions are taken from an external source and downloaded via a network. This is notably the case for the applications. In this case, the computer program product comprises a computer-readable data medium on which program instructions are stored or a data medium signal on which the program instructions are encoded.

The invention relates to a computer program product comprising the computer-readable medium containing instructions which, when they are executed by the data processing circuit, cause the system C to implement the steps of the method according to the invention.

The form of the program instructions is, for example, a form of source code, a computer-executable form, or any form intermediate between source code and a computer-executable form, such as the form resulting from the conversion of the source code via an interpreter, assembler, compiler, link editor, or locator. Alternatively, the program instructions are a microcode, firmware instructions, status definition data, configuration data for integrated circuits (e.g. VHDL) or an object code. The program instructions are written in any combination of one or more programming languages, for example an object-oriented programming language (C++, JAVA, Python), a procedural programming language (for example language C).

The user interface or HMI 11 comprising an input device and an output device. The user interface 11 comprises an input device for allowing the user to enter data or controls, for example the Shim box, so as to be able to interact with the programs according to the invention. The input device comprises, for example, a keyboard or a pointing interface, such as a mouse, an optical pen, a touchpad, a remote control, a voice recognition device, a haptic device.

The output device is designed to render information to a user, sensorily or electrically, such as, for example, visually or acoustically. The output interface comprises, for example, a graphic interface. The output interface may be the input device, for example, in the case of a touch tablet.

The display step is implemented by the output device.

The set of at least one communication device allows communication between the elements of the system C and optionally between at least one element of the system and a device external to the system C, for example system A. This communication device can establish a physical link between elements of the system C and/or between an element of the system C and a device external to the system C and/or a remote (wireless) communication link between elements of the system C and/or between an element of the system and a device external to the system C.

1. A method for determining an optimal characteristic set of at least one characteristic parameter of a medical signal acquisition sequence for the generation of a medical image of an area to be imaged by magnetic resonance, the acquisition sequence being configured to substantially cancel out medical signals from at least one predetermined tissue, the method comprising selecting, with a computer, an optimal characteristic image having a greater number of pixels of intensity less than or equal to a given intensity threshold among a plurality of characteristic images of a characteristic area of the area to be imaged generated from signals acquired by respective acquisition sequences having distinct respective sets of at least one characteristic parameter, the optimal characteristic set being the characteristic set of the signal acquisition sequence by means of which the optimal characteristic image was generated.

2. The method according to claim 1, wherein the medical signal acquisition sequence is a black blood late gadolinium enhancement acquisition sequence.

3. The method according to claim 2, wherein the characteristic area only comprises parts of the myocardium and blood.

4. The method according to claim 1, wherein the characteristic set is an inversion time.

5. The method according to claim 1, comprising determining the intensity threshold comprising:
calculating histograms of the characteristic images of the characteristic area,
determining an intensity of the global maximum of the histograms.

6. The method according to claim 1, comprising selecting characteristic images of the characteristic area among images of the area to be imaged.

7. The method according to claim 1, comprising the following sequence of steps:
acquiring signals by means of the respective acquisition sequences,
generating characteristic images from the signals.

8. The method according to claim 7, wherein the sequence of steps and the selecting of the optimal characteristic image are repeated with inversion times different from those of the acquisition sequences when the optimal inversion time is a maximum or minimum inversion time of the acquisition sequences.

9. A method for generating a medical image of the area to be imaged comprising determining the optimal set of at least one characteristic parameter by the method according to claim 1, and acquiring medical signals by a medical acquisition sequence having the optimal characteristic set and generating the medical image from the medical signals.

10. A processing system comprising a processor configured to implement the steps of the method according to claim 1.

11. A non-transitory computer program product comprising instructions which, when the instructions are executed by a computer, lead the latter to implement the steps of the method according to claim 1.

12. A non-transitory readable recording medium comprising instructions which, when the instructions are executed by a computer, lead the latter to implement the method according to claim 1.

13. A magnetic resonance imaging system comprising a magnetic resonance system comprising a static magnetic field generator, a gradient generator, a radio frequency device, and a processing and control system configured to implement the steps of the method according to claim 1 and to control the magnetic resonance system.
